(19) United States
(12) Patent Application Publication
(10) Pub. No.: US 2004/0160350 A1
(43) Pub. Date: Aug. 19, 2004

(54) Adjustable resistor device for use in integrated circuit

(75) Inventor: Chao-Hsin Lu, Da-Yuan Shiang (TW)

Correspondence Address: BACON & THOMAS, PLLC, 625 SLATERS LANE, FOURTH FLOOR, ALEXANDRIA, VA, 22314

(73) Assignee: Realtek Semiconductor Corp., Hsinchu (TW)

(21) Appl. No.: 10/754,727

(22) Filed: Jan. 12, 2004

(30) Foreign Application Priority Data
Feb. 19, 2003 (TW) 092103428

(51) Int. Cl. H03M 1/78

(52) U.S. Cl. 341/154

(57) ABSTRACT

An adjustable resistor device is disclosed. The adjustable resistor device comprises a resistor and a plurality of metal oxide semiconductor (MOS) transistors coupled to the resistor. The MOS transistors are coupled in parallel and controlled by a plurality of corresponding control signals such that each of the MOS transistors is on either a triode region or a cutoff region.

### BACKGROUND OF THE INVENTION

1. Field of the Invention

The present invention relates to an adjustable resistor device and, more particularly, to an adjustable resistor device for use in an integrated circuit (IC).

2. Description of Related Art

FIG. 1A shows a conventional adjustable resistor device for use in an IC. The adjustable resistor device includes a resistor 10 and a plurality of cascaded resistors 11 and switches 12. Each of the switches 12 is controlled to be turned on or off in order to produce the desired equivalent resistance Req=R//XRp/k, where k is the number of switches 12 that are closed (i.e., switching on). However, Each of the switches 12 can be functionally regarded as to comprise an equivalent resistor. Thus, the size required for each switch 12 usually will be relatively large in order to decrease the effect of the equivalent resistor which may affect the characteristics of the conventional adjustable resistor device. Such a large size required for switches may increase the manufacturing cost for an IC. If the size of the switches 12 is reduced due to the size reduction of the IC, the equivalent resistor of the switches 12 may have a larger impaired affect on the adjustable resistor device. In addition, the stray capacitor effect of the switches 12 may become obvious that it can affect impedance characteristics of the adjustable resistor device. FIG 1B shows that the stray capacitor effect may affect the impedance characteristics of the adjustable resistor device especially at high frequency. This effect may cause an unpredictable impact on the IC operation.

### SUMMARY OF THE INVENTION

The object of the present invention is to provide an adjustable resistor device with smaller IC area requirement and reduced stray capacitor effect.

According to the object of the present invention, an adjustable resistor device is disclosed. The adjustable resistor device comprises a resistor and a plurality of metal oxide semiconductor (MOS) transistors coupled to the resistor. The MOS transistors are coupled in parallel and controlled by a plurality of corresponding control signals such that each of the MOS transistors is on either a triode region or a cutoff region.

Other objects, advantages, and novel features of the invention will become more apparent from the following detailed description when taken in conjunction with the accompanying drawings.

### BRIEF DESCRIPTION OF THE DRAWINGS

FIG. 1A is a conventional adjustable resistor device for use in an integrated circuit;

FIG. 1B is a schematic curve showing the effect of the stray capacitor of the switches on the impedance characteristic of the IC;

FIG. 2 is a circuit diagram of an adjustable resistor device for use in an IC in according with an embodiment of the invention; and

FIG. 3 is a circuit diagram of an adjustable resistor device for use in an IC in according with another embodiment of the invention.

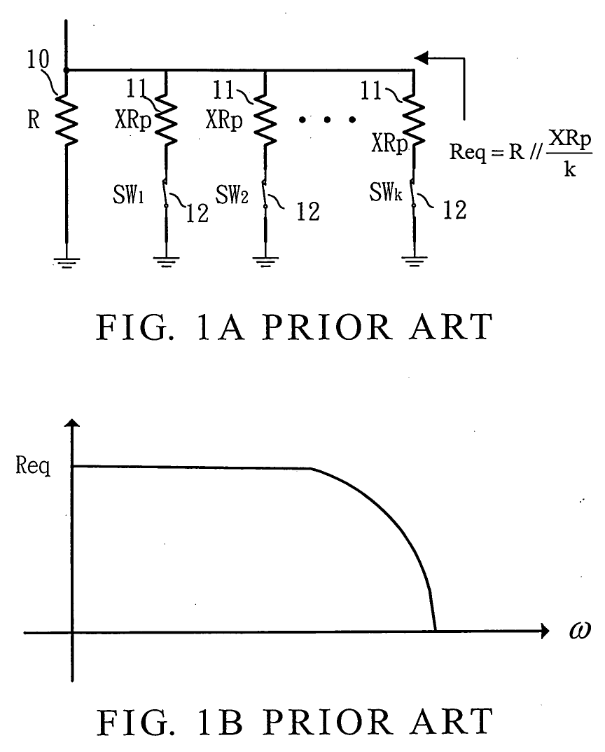

### DETAILED DESCRIPTION OF THE PREFERRED EMBODIMENT

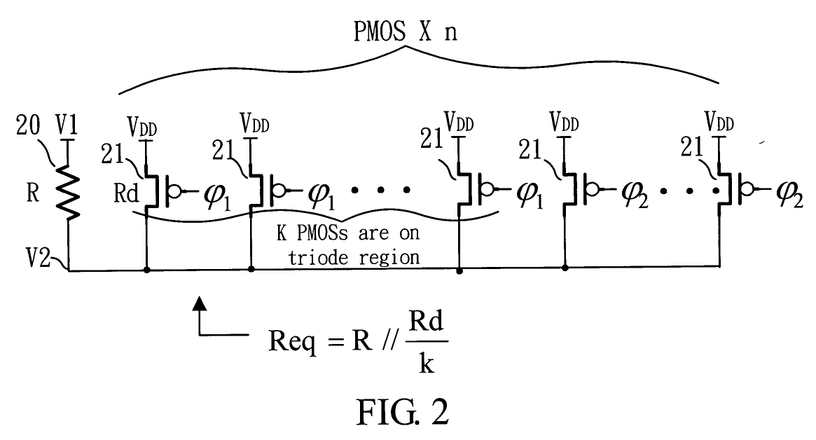

With reference to FIG. 2, there is shown a preferred embodiment of an adjustable resistor device for use in an IC. The adjustable resistor device disclosed in the embodiment includes a resistor 20 and a plurality of MOS transistors 21. In this embodiment, the MOS transistors 21 are PMOS transistors. The resistor 20 is coupled to a high potential V1 at the first end and a low potential V2 at the second end. The PMOS transistors are coupled in parallel and coupled to the resistor 20 at the second end. A plurality of control signals are used to controlling the corresponding MOS transistors 21 to operate on either the triode region or the cutoff region. If the transistor 21 is on the cutoff region, it can be neglected because the resistor 20 with much larger resistance is coupled in parallel to the transistor 21. If the transistor 21 is on the triode region, the equivalent resistor of the transistor 21 should be taken into consideration.

As cited, since the transistors 21 are in the triode region through the controlling of the corresponding control signals. The equivalent resistor of each transistor can be regulated and controlled by controlling the magnitude of the corresponding control signal applying on the gate of the MOS transistors 21.

In this embodiment, if a control voltage Φ 1 is applied to the MOS transistors 21, the corresponding MOS transistors 21 operate on the triode region. If a control voltage Φ 2 is applied to the MOS transistors 21, the corresponding MOS transistors operate on the cutoff region. Thus, an equivalent resistance of the adjustable resistor device is

$$R // \frac{Rd}{k} ,$$

where R is resistance of the resistor 20, Rd is an equivalent resistance of the MOS transistor on the triode region, and k is the number of MOS transistors on the triode region. It should be noted that there is a simplified presumption for the above description that the equivalent resistance of the MOS transistors 21 are the same if they are on the triode region. However, since the equivalent resistor of each transistor can be regulated and controlled by controlling the magnitude of the corresponding control signal, the equivalent resistance of the adjustable resistor device can be in a much more complicated form that

$$R // \frac{Rd1}{k1} // \frac{Rd2}{k2} // \frac{Rd3}{k3} … ,$$

wherein the Rd1, Rd2, Rd3 . . . are the equivalent resistance of the MOS transistors of different groups that the control signals in different magnitude are applied to the MOS transistors of different groups, and k1, k2, k3, . . . are the number of the MOS transistors of each group.

By analyzing the circuit, the sensitivity of the equivalent resistance to the applied voltage is given by:

$$\begin{matrix}\frac{\frac{\partial Req}{\partial V}}{Req} = \frac{\frac{\partial }{\partial V} ( R // \frac{Rd}{k} )}{Req} = \frac{\frac{\partial }{\partial V} ( \frac{R * \frac{Rd}{k}}{R + \frac{Rd}{k}} )}{Req} = \frac{\frac{\partial }{\partial V} ( \frac{R * Rd}{k * R + Rd} )}{Req} \\ = \frac{( k * R + Rd ) \frac{\partial R * Rd}{\partial V} - ( R * Rd ) \frac{\partial ( k * R + Rd )}{\partial V}}{{( k * R + Rd )}^{2}} * \frac{1}{Req} \\ = \frac{R ( k * R + Rd ) \frac{\partial Rd}{\partial V} - ( R * Rd ) \frac{\partial ( Rd )}{\partial V}}{{( k * R + Rd )}^{2}} * \frac{1}{( \frac{R * Rd}{k * R + Rd} )} \\ = \frac{R ( k * R ) \frac{\partial Rd}{\partial V}}{R * Rd * ( k * R + Rd )} = \frac{k * R}{Rd * ( k * R + Rd )} * \frac{\partial Rd}{\partial V} < \frac{\partial Rd}{\partial V}\end{matrix} \qquad ( 1 )$$

From the equation (1), the sensitivity of the equivalent resistance to the applied voltage can be effectively reduced. That is, the resistance of the equivalent resistor of the transistors 21 can be less sensitive to the change of the applied voltage VDD. Thus, the adjustable resistor device of FIG. 2 may be much more stable in operation.

It should be noted that a MOS transistor requires a much smaller area than a resistor. Thus, the adjustable resistor device of the embodiment of the present invention may require much smaller IC area and is much more suitable for use in an IC. Besides, since large-size switches are not needed, the stray capacitor effect may be reduced. In addition, the control signals may be provided by an external circuit. Alternatively, the magnitude of the control signal can be either predetermined or dynamically regulated.

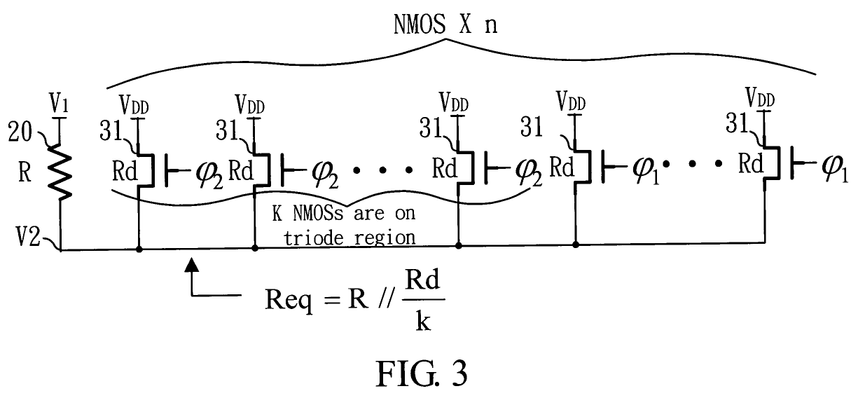

FIG. 3 is a circuit diagram of an adjustable resistor device for use in an IC in according with another embodiment of the invention. As shown, this embodiment is similar to the previous one except that the MOS transistors are NMOS transistors in this embodiment.

Furthermore, although the previously described two embodiments in FIG. 2 and FIG. 3 are employing MOS transistors as equivalent resistor providers, they are not meant to serve as limitations. It should be appreciated by one who is skilled in the art that other types of transistors, such as BJT or the like, may be substituted into the location of the MOS transistors to serve the same purpose when properly situated and designed.

Although the present invention has been explained in relation to its preferred embodiment, it is to be understood that many other possible modifications and variations can be made without departing from the spirit and scope of the invention as hereinafter claimed.

What is claimed is:

1. An adjustable resistor device, comprising:
a resistor; and
a plurality of transistors coupled to the resistor, wherein the transistors are coupled in parallel and controlled by a plurality of corresponding control signals such that each of the transistors is on either a triode region or a cutoff region.

2. The adjustable resistor device as claimed in claim 1, wherein the transistors are metal oxide semiconductor (MOS) transistors.

3. The adjustable resistor device as claimed in claim 2, wherein the MOS transistors are PMOS transistors.

4. The adjustable resistor device as claimed in claim 2, wherein the MOS transistors are NMOS transistors.

5. The adjustable resistor device as claimed in claim 2, wherein the MOS transistors are CMOS transistors.

6. The adjustable resistor device as claimed in claim 1, wherein the equivalent resistance of each of the transistor is determined by the magnitude of the corresponding control signal.

7. The adjustable resistor device as claimed in claim 1, wherein the adjustable resistor device further includes a control circuit for providing the control signals.

8. The adjustable resistor device as claimed in claim 7, wherein the magnitude of each of the control signals is predetermined.

9. The adjustable resistor device as claimed in claim 7, wherein the magnitude of each of the control signals is adjustable.

10. An adjustable resistor device, comprising:
a plurality of transistors coupled in parallel and controlled by a plurality of corresponding control signals such that each of the transistors is on either a triode region or a cutoff region;
wherein the equivalent resistance of the adjustable resistor device can be determined by the magnitude of each of the corresponding control signals.

11. The adjustable resistor device as claimed in claim 10, wherein the adjustable resistor device further includes a control circuit for providing the control signals.

12. The adjustable resistor device as claimed in claim 11, wherein the magnitude of each of the control signals is predetermined.

13. The adjustable resistor device as claimed in claim 11, wherein the magnitude of each of the control signals is adjustable.

14. The adjustable resistor device as claimed in claim 10, wherein the transistors are metal oxide semiconductor (MOS) transistors.
